(19) United States
(12) Patent Application Publication
(10) Pub. No.: US 2022/0044143 A1
(43) Pub. Date: Feb. 10, 2022

(54) Simulation Method in Quantum Control, Classical Computer, and Storage Medium

(71) Applicant: BEIJING BAIDU NETCOM SCIENCE TECHNOLOGY CO., LTD., BEIJING (CN)

(72) Inventors: Lijing Jin, Beijing (CN); Xin Wang, Beijing (CN); Zelin Meng, Beijing (CN)

(73) Assignee: BEIJING BAIDU NETCOM SCIENCE TECHNOLOGY CO., LTD.

(21) Appl. No.: 17/503,933

(22) Filed: Oct. 18, 2021

(30) Foreign Application Priority Data
Nov. 27, 2020 (CN) 202011358498.0

(51) Int. Cl. G06N 10/00; G06F 30/367

(52) U.S. Cl. CPC G06N 10/00; G06F 30/367

(57) ABSTRACT

A simulation method in quantum control is provided, which is related to a field of quantum control. The specific implementation scheme includes: acquiring a hardware parameter corresponding to a quantum system and a target quantum gate required to be realized by the quantum system; acquiring a pulse function represented on the basis of discrete time slices; determining target step sizes corresponding to the discrete time slices in the pulse function, to obtain pulse parameter values within time durations corresponding to the target step sizes corresponding to the time slices and the pulse function; and obtaining simulation quantum gates within the time durations corresponding to the target step sizes on the basis of obtained pulse parameter values within the time durations corresponding to the target step sizes and the hardware parameter of the quantum system, until obtaining a target simulation quantum gate within a preset pulse time duration.

### CROSS-REFERENCE TO RELATED APPLICATIONS

This application claims priority to Chinese patent application, No. 202011358498.0, entitled “Simulation Method and Apparatus in Quantum Control, Classical Computer, and Storage Medium”, filed with the Chinese Patent Office on Nov. 27, 2020, which is hereby incorporated by reference in its entirety.

### TECHNICAL FIELD

The present disclosure relates to a field of quantum computation, in particular to a field of quantum control.

### BACKGROUND

Quantum control is a bridge for connecting quantum software and hardware, and also an indispensable component of quantum computation.

### SUMMARY

According to the present disclosure, it is provided a simulation method and apparatus in quantum control, a classical computer, and a storage medium.

According to an aspect of the present disclosure, it is provided a simulation method in quantum control, including:

acquiring a hardware parameter corresponding to a quantum system and a target quantum gate required to be realized by the quantum system;

acquiring a pulse function represented on the basis of discrete time slices, wherein pulse parameter values within a time period from start time to end time of a time slice are the same;

determining target step sizes corresponding to the discrete time slices in the pulse function, to obtain pulse parameter values within time durations corresponding to the target step sizes according to the target step sizes corresponding to the time slices and the pulse function; and

obtaining simulation quantum gates within the time durations corresponding to the target step sizes on the basis of obtained pulse parameter values within the time durations corresponding to the target step sizes and the hardware parameter of the quantum system, until obtaining a target simulation quantum gate within a preset pulse time duration, wherein a difference between the target simulation quantum gate within the preset pulse time duration and the target quantum gate meets a preset rule.

According to another aspect of the present disclosure, it is provided a simulation apparatus in quantum control, including:

a data acquisition unit used for acquiring a hardware parameter corresponding to a quantum system and a target quantum gate required to be realized by the quantum system;

a function acquisition unit used for acquiring a pulse function represented on the basis of discrete time slices, wherein pulse parameter values within a time period from start time to end time of a time slice are the same;

a step size determination unit used for determining target step sizes corresponding to the discrete time slices in the pulse function;

a pulse parameter value determination unit used for obtaining pulse parameter values within time durations corresponding to the target step sizes according to the target step sizes corresponding to the time slices and the pulse function; and

a simulation unit used for obtaining simulation quantum gates within the time durations corresponding to the target step sizes on the basis of obtained pulse parameter values within the time durations corresponding to the target step sizes and the hardware parameter of the quantum system, until obtaining a target simulation quantum gate within a preset pulse time duration, wherein a difference between the target simulation quantum gate within the preset pulse time duration and the target quantum gate meets a preset rule.

According to yet another aspect of the present disclosure, it is provided a classical computer, including:

at least one processor; and

a memory communicatively connected to the at least one processor, wherein

the memory stores instructions executable by the at least one processor, and the instructions are executed by the at least one processor to enable the at least one processor to execute the method as mentioned above.

According to yet another aspect of the present disclosure, there is provided a non-transitory computer-readable storage medium storing computer instructions, wherein the computer instructions, when executed by a computer, cause the computer to execute the method as mentioned above.

It should be understood that the content described in this section is not intended to identify the key or critical features of embodiments of the present disclosure, nor is it intended to limit the scope of the disclosure. Other features of the present disclosure will become readily apparent from the following description.

### BRIEF DESCRIPTION OF THE DRAWINGS

The accompanying drawings are included to provide a better understanding of the scheme and are not to be construed as limiting the present disclosure. In the drawings:

FIG. 1 is a schematic flowchart showing an implementation of a simulation method in quantum control according to an embodiment of the present disclosure;

FIG. 2 is schematic diagram I showing a discrete time slice in a specific scenario according to an embodiment of the present disclosure;

FIG. 3 is schematic diagram II showing a discrete time slice in a specific scenario according to an embodiment of the present disclosure;

FIG. 4 is a schematic flow diagram showing a simulation method in quantum control in a specific example according to an embodiment of the present disclosure;

FIG. 5 is schematic structural diagram showing a simulation apparatus in quantum control according to an embodiment of the present disclosure; and

FIG. 6 is a block diagram of a classical computer for a simulation method in quantum control according to an embodiment of the present disclosure.

### DETAILED DESCRIPTION

The following describes exemplary embodiments of the present disclosure with reference to the accompanying drawings, which includes various details of embodiments of the present disclosure to facilitate understanding and should be considered as merely exemplary. Accordingly, one of ordinary skilled in the art appreciates that various changes and modifications can be made to the embodiments described herein without departing from the scope and spirit of the present disclosure. Similarly, descriptions of well-known functions and structures are omitted from the following description for clarity and conciseness.

In quantum computation, except for considering the performance of quantum hardware (including the quality and quantity of qubits), quantum hardware needs to be effectively controlled, so that quantum algorithms and quantum information processing schemes can be efficiently executed. Specifically, a quantum logic gate (i.e., quantum gate) at the quantum software level needs to be compiled into physical pulse signals that can be recognized by quantum hardware. In this process, the fidelity and speed of the quantum gate implemented by the compilation are critical. Therefore, it means that there is a need to realize quantum control technology for a quantum gate with high precision rapidly. So, how to realize quantum simulation rapidly and accurately becomes the core of quantum control technology.

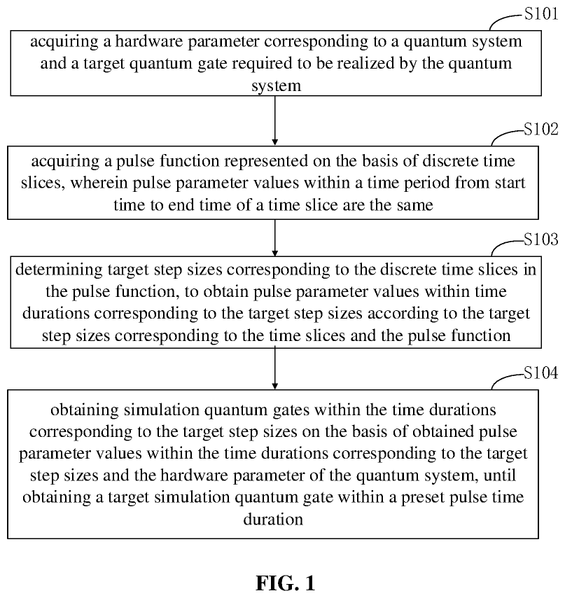

According to an embodiment of the present disclosure, it is provided a simulation method in quantum control. Specifically, FIG. 1 is a schematic flowchart showing an implementation of a simulation method in quantum control according to an embodiment of the present disclosure. As shown in FIG. 1, the method includes:

S101: acquiring a hardware parameter corresponding to a quantum system and a target quantum gate required to be realized by the quantum system;

S102: acquiring a pulse function represented on the basis of discrete time slices, wherein pulse parameter values within a time period from start time to end time of a time slice are the same;

S103: determining target step sizes corresponding to the discrete time slices in the pulse function, to obtain pulse parameter values within time durations corresponding to the target step sizes according to the target step sizes corresponding to the time slices and the pulse function; and

S104: obtaining simulation quantum gates within the time durations corresponding to the target step sizes on the basis of obtained pulse parameter values within the time durations corresponding to the target step sizes and the hardware parameter of the quantum system, until obtaining a target simulation quantum gate within a preset pulse time duration, wherein a difference between the target simulation quantum gate within the preset pulse time duration and the target quantum gate meets a preset rule.

Therefore, according to the scheme provided by the present disclosure, the time can be sliced so that the quantum simulation can be rapidly and accurately realized, and the target simulation quantum gate acquired in the simulation process can be considered to be the target quantum gate planned to be realized, so that a foundation is laid for more efficient realization of the quantum gate.

In practical applications, the quantum system is a system formed by quantum hardware, and the hardware parameter is a parameter corresponding to the quantum hardware. For example, for a superconducting quantum circuit, the hardware parameter can be specifically a parameter such as frequency and detuning intensity of a superconducting qubit.

In one example, the time information of the pulse function can be discretized in the following way, such that a pulse function characterized on the basis of a discrete time slice is acquired. Specifically, the pulse function cₖ (t) is approximately divided into a time-discrete slice sequence, wherein the start time of the i (i≥1)^{th} slice is tᵢ₋₁, the end time is tᵢ, the time span (i.e. step size) is Δtᵢ=tᵢ−tᵢ₋₁, and the height (i.e. pulse parameter value) of the i (i≥1)^{th} slice is constantly

$${c}_{k} ( \frac{{t}_{i - 1} + {t}_{i}}{2} ) .$$

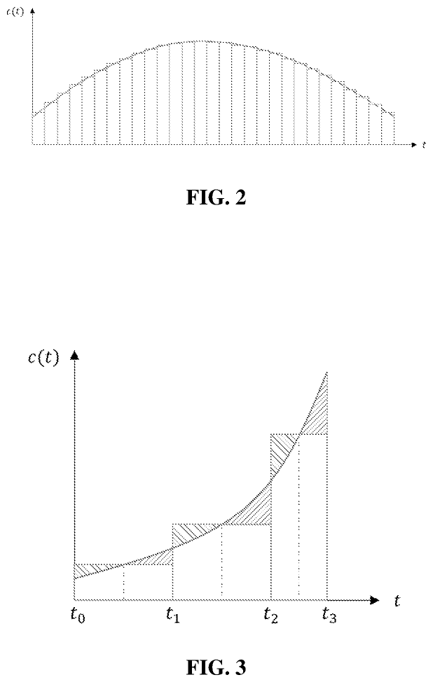

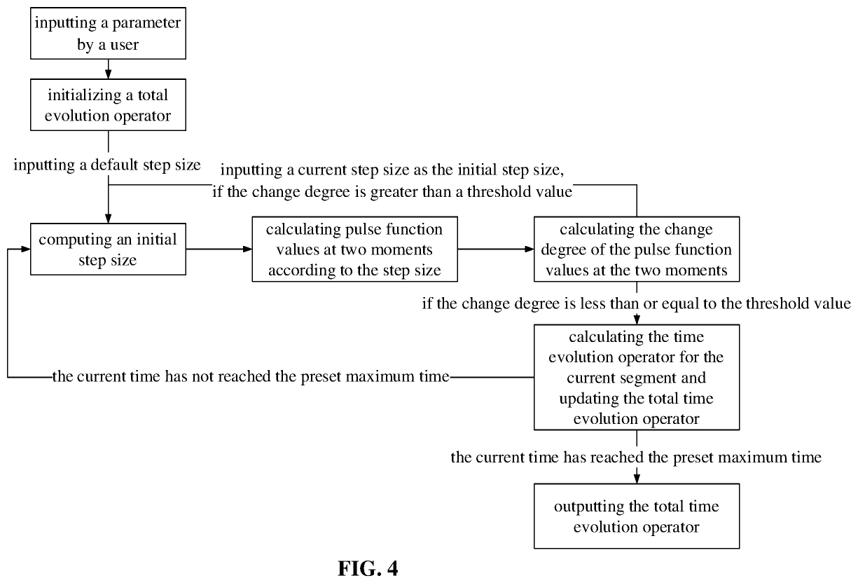

In a specific example of a scheme of the present disclosure, the target step sizes corresponding to respective time slices are the same or different. For example, after the time information of the pulse function is discretized, the time span (i.e., the target step size) of each time slice is the same. As the result of the discretization shown in FIG. 2, the step size corresponding to each time slice is the same, and the height (pulse parameter value) of the pulse within each time slice is constant. Of course, as shown in FIG. 3, the time spans (i.e., target step sizes) of the different time slices are different or need not be the same. As a result of the discretization shown in FIG. 3, the step sizes corresponding to respective time slices are not the same, but the height of the pulses (pulse parameter values) within each time slice is constant. Therefore, the purpose of dynamically determining the target step size is achieved, the foundation is further laid for simplifying the computing process and improving the computing efficiency, and the foundation is also laid for acquiring the target quantum gate through subsequent rapid and accurate simulation. In addition, since the target step sizes can be the same or different, both the error (the difference between the target simulation quantum gate and the target quantum gate) and the computing efficiency can be considered, so that the flexibility of the scheme of the present disclosure is improved.

In a specific example of the scheme of the present disclosure, the target step size can be acquired in the following manner. Specifically, the target step size corresponding to the discrete time slice in the pulse function is determined, which includes: acquiring a first initialization step size (for example, as a preset value); obtaining a difference value between pulse parameter values at adjacent moments by calculating based on the first initialization step size and the pulse function; and taking the first initialization step size as the target step size, in response to determining that the difference value between the pulse parameter values at the adjacent moments is smaller than a preset pulse threshold value and a time period corresponding to the first initialization step size does not exceed the preset pulse time duration (that is, in response to determining that the time period of the target step size does not exceed the preset pulse time). For example, as shown in FIG. 3, assuming that the period of the target step size currently to be determined is (t₁, t₂) period and the preset pulse time is t_{g}, at such time, whenever the (t₁, t₂) period is within t_{g}, for example, t_{g} corresponds to the t₃ moment in FIG. 3, at which time t₂ precedes t₃, that is, (t₁, t₂) period is within t_{g}, and at such time, the first initialization step size can be taken as the target step size. Otherwise, the operation is stopped.

As such, the target step size corresponding to each time slice is acquired, so that the foundation is laid for simplifying the computing process, and the foundation is also laid for acquiring the target quantum gate through subsequent rapid and accurate simulation.

In a specific example of the scheme of the present disclosure, the target step size can be acquired in the following manner. Specifically, the determining the target step size corresponding to the discrete time slices in the pulse function includes: acquiring a second initialization step size; obtaining a difference value between pulse parameter values at adjacent moments by calculating based on the second initialization step size and the pulse function; adjusting the second initialization step size in response to determining that the difference value between the pulse parameter values at the adjacent moments is greater than or equal to a preset pulse threshold value, until a difference value between pulse parameter values at adjusted adjacent moments is smaller than the pulse threshold value; and taking an adjusted second initialization step size with a difference value between pulse parameter values at adjacent moments smaller than the pulse threshold value as the target step size, in response to determining that a time period corresponding to the adjusted second initialization step size does not exceed the preset pulse time duration.

Similar to the above example, this example provides a case where the difference between the pulse parameter values at adjacent moments is greater than or equal to a preset pulse threshold, at which time the target step size can be adjusted, for example, by reducing the target step size, so that the condition that the difference between the pulse parameter values at the adjacent moments is less than the pulse threshold is satisfied. Therefore, the scheme for dynamically determining the step size is improved, thereby laying a foundation for simplifying the computing process, and also laying a foundation for acquiring the target quantum gate through subsequent rapid and accurate simulation.

Here, it is to be noted that in practical applications, the first initialization step size and the second initialization step size may be unified as preset step sizes of preset settings.

In a specific example of the scheme of the present disclosure, a data processing rule of a time evolution operator can be acquired in the following manner, and in turns a simulation quantum gate is acquired based on the data processing rule. Specifically, before S104, the following steps are further included: determining a total Hamiltonian corresponding to the quantum system and obtaining a first mapping relation between a time evolution operator and the total Hamiltonian, for example, the first mapping relation can be specifically a linear Schrodinger equation; wherein the total Hamiltonian at least includes a pulse Hamiltonian, and the pulse Hamiltonian includes the pulse function related to time information for controlling pulses; further, determining a data processing rule of the time evolution operator by performing a mathematical transformation on the first mapping relation based on the pulse function represented on the basis of the discrete time slices; finally, after the data processing rule is determined, obtaining the simulation quantum gates within the time durations corresponding to the target step sizes on the basis of the obtained pulse parameter values within the time durations corresponding to the target step sizes and the hardware parameter of the quantum system specifically includes: inputting the obtained pulse parameter values within the time durations corresponding to the target step sizes and the hardware parameter of the quantum system into the data processing rule, to obtain the simulation quantum gates within the time durations corresponding to the target step sizes. In other words, in practical applications, after the time information of the pulse function is discretized, the total Hamiltonian can be subjected to mathematical transformation based on the pulse function characterized on the basis of the discrete time slice, and then a data processing rule is further acquired. According to the data processing rule, the simulation quantum gate can be acquired based on the pulse parameter value and the hardware parameter of the quantum system. Therefore, quantum simulation is realized, and a target simulation quantum gate is acquired. The target simulation quantum gate is the target quantum gate planned to be realized, so that a foundation is laid for a more efficient realization of the quantum gate.

As such, according to the scheme provided by the present disclosure, the time can be sliced so that the quantum simulation can be rapidly and accurately realized, and the target simulation quantum gate acquired in the simulation process can be considered to be the target quantum gate planned to be realized, so that a foundation is laid for more efficient realization of the quantum gate.

The scheme of the present disclosure is described in further detail in combination with a specific example. Specifically, the example proposes a quantum simulation method for quantum control and based on an ordinary differential equation for solution, which is also called a quantum simulation method for discrete time approximate solution based on dynamic step size. According to the scheme of the present disclosure, the step size of the discrete time in the evolution process of the computing system can be dynamically adjusted according to an actually required target quantum gate in the generation process used for controlling the pulse function of the quantum gate, and the pulse parameter value used for acquiring the target quantum gate is further adjusted, therefore, the time for computing the target pulse parameter value of the target quantum gate is greatly reduced, and the precision of an operation result can be guaranteed.

In practical applications, an experimenter can directly apply the scheme of the present disclosure to experiments according to different use scenarios, or further improve the fidelity of the quantum gate by taking the pulse function given by the technical scheme and combining with other optimization schemes, to which the scheme of the present disclosure is not limited.

The scheme of the present disclosure is described in detail from two aspects below. The first component illustrates the core idea and key steps of the scheme of the present disclosure, and the second component focuses on displaying the effects and advantages of the scheme of the present disclosure.

Specifically, in the first component, a step of acquiring the time evolution operator after the “Runge-Kutta” algorithm is optimized on the basis of “the discrete time approximate solution method of the dynamic step size” is illustrated, that is, the time evolution operator is acquired by combining the discrete time approximate solution method of the dynamic step size and the Runge-Kutta algorithm, and a specific simulation flow is illustrated.

The scheme of the present disclosure provides a novel generation scheme of a control pulse (i.e. a pulse function) for controlling a quantum gate, and the core of the generation scheme is to introduce a “discrete time approximate solution method of dynamic step size” (hereinafter referred to as a “dynamic step size method”) to process the pulse function to acquire a time evolution operator through the solution, and the time evolution operator is a simulation quantum gate computed in a simulation process. In the solving process, the time information of the pulse function is sliced, and the target step size corresponding to each time slice can be dynamically determined, so that the possibility of acquiring the target simulation quantum gate through rapid simulation is provided. The target simulation quantum gate is the target quantum gate planned to be realized, and the foundation is laid for a more efficient realization of the quantum gate. In the process, it is only necessary to determine relevant parameters of a target quantum gate and quantum hardware that are desired to be realized, and then the optimized target pulse value required to be applied can be rapidly, stably, and accurately output.

More specifically, according to the scheme of the present disclosure, in the initialization process of the pulse function, a first-order “dynamic step size method” and a “Runge-Kutta” mixed method are adopted to solve the time-dependent (i.e. including a time parameter, hereinafter referred to as time-dependent) Schrodinger equation satisfied by the time evolution operator, and a Nelder-Mead optimization method is further used to acquire the pulse parameter.

Here, it should be noted that the optimization method provided by the example may use other optimization algorithms as well, that is, the Nelder-Mead optimization method is merely exemplary and is not intended to limit the scheme of the present disclosure.

Further, in order to illustrate the scheme of the present disclosure more clearly, the core idea and key steps of the scheme of the present disclosure are fully illustrated by taking the implementation of a superconducting single-bit quantum gate as an example. It is important to note that the present scheme of the present disclosure also supports a plurality of qubit quantum gates as well as other quantum systems, to which no limitation is made herein.

The core idea of the scheme of the present disclosure includes: solving a Schrodinger equation satisfied by a quantum system (i.e., a system formed by quantum hardware) by using a “dynamic step size method”, specifically:

given the Hamiltonian H(t) of one quantum system, the kinetic equation satisfied by the time evolution operator U(t) can be described by one linear Schrodinger equation (i.e., equation (1) below):

$$i ℏ \frac{\partial }{\partial t} U ( t ) = H ( t ) U ( t ) , \qquad ( 1 )$$

where i is an imaginary unit and h is Planck constant. In order to solve the time-dependent differential equation, the “discrete time approximate solution method of dynamic step size” is used. A “discrete time approximate solution method of dynamic step size” is described in detail below, including the content as follows.

In the quantum optimal control problem, the Hamiltonian of a quantum system can be expressed as:

Hₜₒₜₐₗ(t)=H_{drift}+H_{ctrl}(t) (2)

where Hₜₒₜₐₗ (t) corresponds to H(t) in the above-mentioned equation (1), and H_{drift} is the time-independent drift Hamiltonian, generally describing the hardware structure of the quantum system. H_{ctrl} (t) is a Hamiltonian containing a pulse function and can be written as follows:

H_{ctrl}(t)=Σₖ₌₁^{N}cₖ(t)Hₖ, (3)

where cₖ (t) (k=1, 2, . . . ,N) is an envelope function describing the k^{th} pulse waveform, which is generally time-dependent; Hₖ is a time-independent control operator (characterizing the coupling of pulses to quantum systems). It can be seen that in the quantum optimal control problem, the time-dependent component describes only the pulse waveform (i.e. the pulse function). Based on this property, the pulse function cₖ (t) in the evolution process is approximately divided into time-discrete slice sequences, in which the start time of the i (i≥1)^{th} slice is tᵢ₋₁, the end time is t₁, the time span is Δtᵢ=tᵢ−tᵢ₋₁, and the height of the i (i≥1)^{th} slice is constant as

$${c}_{k} ( \frac{{t}_{i - 1} + {t}_{i}}{2} ) .$$

If the time span of each slice sequence is the same, the result of the discretization shown in FIG. 2 is acquired, where the pulse height (pulse parameter value) is constant within each slice, i.e., corresponding to a time-independent Hamiltonian

$${H}_{i} = H ( \frac{{t}_{i - 1} + {t}_{i}}{2} ) .$$

Therefore, the matrix exponential solution can be used to solve its time evolution operator:

U(t)=exp(−iHᵢΔtᵢ), (4)

where exp denotes the matrix exponential operation and Hᵢ represents Hₜₒₜₐₗ at moment tᵢ, here, since Hᵢ is related to the pulse function, and as such, the resulting time evolution operator U(t) is also related to the pulse function. As such, after the pulse parameter value of the pulse function is initialized, the U value corresponding to the initialized pulse parameter value can be acquired on the basis of the formula (4), and the U value is the quantum gate in the simulation process, namely the simulation quantum gate.

Here, as can be seen from FIG. 2, the larger the time span of the slice is, the larger the error, and the shorter the time consumed by computing. The smaller the time span of the slice is, the smaller the error, but the longer the time consumed by computing. Therefore, the present disclosure can dynamically select an appropriate step size based on the specific property of the pulse function to maximally improve the computing speed in the tolerance range of the error.

Of course, to simplify the computing process, improve the computing efficiency, and to ensure that under the premise that the computing result satisfies the precision requirement, the time spans (i.e., target step sizes) of different time slices are different, or need not be the same. As shown in FIG. 3, the step sizes corresponding to respective time slices are different, but the pulse height (pulse parameter values) within each time slice is constant.

As shown in FIG. 4, the specific steps of the scheme of the present disclosure include as follows.

Step 1: input, i.e., inputting preset pulse time t_{g}, time-independent drift Hamiltonian H_{drift}, Hamiltonian containing pulse function H_{ctrl}, and the corresponding pulse function cₖ (t), default step size δt, slice maximum change threshold (pulse threshold) μ.

Step 2: the total time evolution operator (i.e., the evolution operator described in FIG. 4) is initialized U(t)=I, i.e., t₀=0, U(0)=I, where I is the identity matrix and t₀=0.

Step 3: the discrete time step size is dynamically adjusted according to the change degree, including:

(1) computing an initial step size: Δt=min{δt, t_{g}−tⱼ};

(2) computing a function value of the pulse function: setting the start time point as tⱼ, and computing c(tⱼ)=Σₖcₖ(tⱼ); and computing according to the step size Δt to acquire the next moment c(tⱼ+Δt)=Σₖcₖ(tⱼΔt); and

(3) computing the change degree: Δc(tⱼ)=c(tⱼ+Δt)−c(tⱼ); if Δc(tⱼ) is greater than the preset threshold value μ, then Δt is set as Δt/2, and the first step (1) in step 3 is re-executed; if Δc(tⱼ) is less than the preset threshold value μ, step 4 is entered.

Step 4: computing the time evolution operator: computing a time evolution operator by using a matrix index according to the step size Δt determined in step 3: Uⱼ(t)=e^{-iH(t}^{ⱼ}^{+Δt/2)Δt} where H described in the formula is Hₜₒₜₐₗ, that is, Hₜₒₜₐₗ at moment tⱼ+Δt, i is an imaginary number, in other words, the simulation quantum gate Uⱼ(t) at moment tⱼ+Δt is acquired; updating U(t)←Uⱼ(t)U(t) and tⱼ←tⱼ+Δt.

Step 5: step 3 and step 4 are repeatedly executed until tⱼ≥t_{g} (i.e. the current time reaches a preset maximum time, which is a preset pulse time).

Step 6: the returned U (t_{g}) is a time evolution operator of the whole pulse function, namely a target simulation quantum gate, and the target simulation quantum gate can be considered to be a target quantum gate expected to be realized. In other words, the target quantum gate can be realized by applying the target pulse parameter value at the moment t_{g} corresponding to the target simulation quantum gate to the quantum system. Moreover, the time evolution operator fully considers the function nature of the pulse function, and satisfies the quantum gate error requirement.

In the second component, the effect presentation of the technical scheme includes the following.

In order to verify the effectiveness and advantages of the above-mentioned technical scheme, a controlled-Z gate (Controlled-Z gate) of a superconducting qubit is tested as an example. In the following test, the pulse parameters of the Controlled-Z gate under given hardware parameters are computed by using an optimization algorithm and a “discrete time approximate solution method of dynamic step size”, so that the Controlled-Z gate with high precision is realized. Meanwhile, a high-precision Runge-Kutta algorithm is used for benchmarking the operation result. To simplify the model, only a three-level quantum system is considered here (i.e. each superconducting qubit is considered as one three-level quantum system). Here, two directly coupled superconducting qubits are used, whose superconducting qubit frequencies are ω₁=5.805×2π GHZ and ω₂=5.205×2π GHZ, respectively. The detuning strengths of the superconducting qubits are α₁=−0.217×2π GHZ and α₂=−0.226×2π GHZ respectively, the target quantum gate U_{goal} is taken to be a Controlled-Z gate, that is:

$${U}_{goal} = [ \begin{matrix}1 & 0 & 0 & 0 \\ 0 & 1 & 0 & 0 \\ 0 & 0 & 1 & 0 \\ 0 & 0 & 0 & - 1\end{matrix} ] . \qquad ( 5 )$$

In general, a Controlled-Z gate can be achieved by applying a magnetic flux to the superconducting qubit 1 (i.e., regulating and controlling the frequency of the superconducting qubit 1). Based on this, the Hamiltonian of the above scheme can be expressed as:

$$H = {ω}_{1} {\hat{a}}_{1}^{†} {\hat{a}}_{1} + {ω}_{2} {\hat{a}}_{2}^{†} {\hat{a}}_{2} + \frac{{α}_{1}}{2} {\hat{a}}_{1}^{†} {\hat{a}}_{1}^{†} {\hat{a}}_{1} {\hat{a}}_{1} + \frac{{α}_{2}}{2} {\hat{a}}_{2}^{†} {\hat{a}}_{2}^{†} {\hat{a}}_{2} {\hat{a}}_{2} + \frac{g}{2} ( {\hat{a}}_{1} {\hat{a}}_{2}^{†} + {\hat{a}}_{1}^{†} {\hat{a}}_{2} ) + \frac{c ( t )}{2} {\hat{a}}_{1}^{†} {\hat{a}}_{1} , \qquad ( 6 )$$

where c(t) is a pulse function, and is expressed by square-wave-like represented by an error function, namely:

$$c ( t ) = \frac{A}{4} [ 1 + erf ( \sqrt{π} \frac{s}{A} ( t - {t}_{s} ) ) \times erfc ( \sqrt{π} \frac{s}{A} ( t - {t}_{e} ) ) ] , \qquad ( 7 )$$

where A, s, tₛ, tₑ are pulse parameters in a pulse function that needs to be optimized to acquire a Controlled-Z gate with high fidelity.

An optimization is performed by adopting the scheme of the present disclosure, a time evolution operator Uᵣₑₐₗ, namely a target simulation quantum gate, of the Hamiltonian of the above formula (6) is computed by using a “discrete time approximate solution method of dynamic step size”, the target simulation quantum gate is projected to a superconducting qubit space, and a distortion function of the simulation quantum gate is computed through the following formula:

g(A,s,tₛ,tₑ)=1−¼|Tr(U_{goal}†Uᵣₑₐₗ)|, (8)

where Tr represents the trace of the matrix. The distortion function is the optimization objective function used in this test, and the optimization objective is to minimize the objective function.

The results of the test are shown below. Firstly, the solving time acquired by the method in the scheme of the present disclosure is compared with that acquired by the existing method. Here, in the scheme of the present disclosure, the maximum change threshold value μ=0.2, and at this time, the results of the solution of the scheme of the present disclosure and the existing method are as follows:

| | The scheme of the | | |
|---|---|---|---|
| | present disclosure | Distortion Tested | |
| Numerical | Distortion/Time | by the Existing | Error |
| Experiment | Consumption | Method | Magnitude |
| 1 | 0.613 × 10⁻³/0 min 5 sec | 0.732 × 10⁻³ | 10⁻⁴ |
| 2 | 0.694 × 10⁻³/0 min 7 sec | 0.683 × 10⁻³ | 10⁻⁵ |
| 3 | 8.767 × 10⁻³/0 min 23 sec | 8.642 × 10⁻³ | 10⁻⁴ |
| 4 | 1.337 × 10⁻³/0 min 7 sec | 1.217 × 10⁻³ | 10⁻⁴ |

Here, in the scheme of the present disclosure, the maximum change threshold value μ=0.002, and at this time, the results of the solution of the scheme of the present disclosure and the existing method are as follows:

| | Discrete Time | | |
|---|---|---|---|
| | Approximate Solution | | |
| | Method of Dynamic | Distortion | |
| Numerical | Step Size Distortion/ | Tested by the | Error |
| Experiment | Time Consumption | Existing Method | Magnitude |
| 1 | 3.3509 × 10⁻⁴/0 min 59 sec | 3.3549 × 10⁻⁴ | 10⁻⁷ |
| 2 | 3.7439 × 10⁻⁴/1 min 13 sec | 3.7430 × 10⁻⁴ | 10⁻⁸ |
| 3 | 7.8431 × 10⁻³/2 min 52 sec | 7.8492 × 10⁻³ | 10⁻⁶ |
| 4 | 8.9137 × 10⁻³/1 min 59 sec | 8.9133 × 10⁻³ | 10⁻⁷ |

The time consumption and fidelity of using existing algorithms with the same precision to perform solution, such as the existing Runge-Kutta method, are as follows:

| | Distortion/Time |
|---|---|
| Numerical | Consumption of the |
| Experiment | Existing Runge-Kutta |
| 1 | 7.19 × 10⁻³/5 min 36 sec |
| 2 | 2.01 × 10⁻³/7 min 05 sec |
| 3 | 3.99 × 10⁻³/2 min 53 sec |
| 4 | 0.84 × 10⁻³/12 min 25 sec |

Therefore, the computing speed can be greatly improved by using the dynamic slice of the scheme of the present disclosure, and the error is in a controllable range.

Compared with other existing quantum simulation methods used in quantum regulation and controlling, the scheme of the present disclosure has remarkable advantages in the following points.

1. The speed is fast, i.e., the pulse generation speed of the scheme of the present disclosure can be increased more than ten times or dozens of times compared with the conventional Runge-Kutta technology.

2. The practicability is strong, namely in superconducting quantum computing, under the condition of using square-wave-like pulses, according to the scheme of the present disclosure, the speed can be remarkably improved, and the method has strong practicability.

3. The extension is strong, namely, more pulse numbers can be increased as required, so that richer pulse waveforms can thus be acquired. In addition, extensions can also be performed on a controlled channel.

4. The flexibility is high, namely different maximum change thresholds can be set according to actual requirements to control the computing precision, so that the method is more flexible compared with the existing scheme.

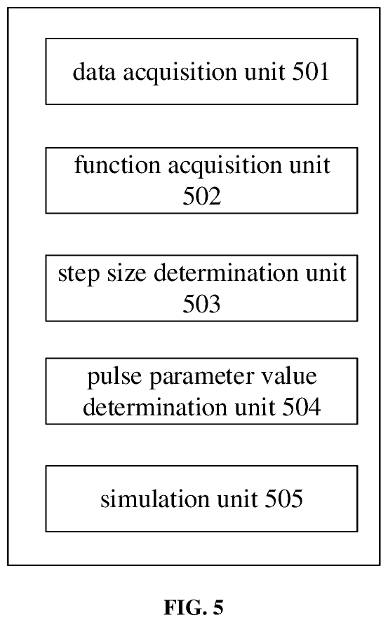

According to the scheme of the present disclosure, as shown in FIG. 5, it is also provided a simulation device in quantum control, including:

a data acquisition unit 501 used for acquiring a hardware parameter corresponding to a quantum system and a target quantum gate required to be realized by the quantum system;

a function acquisition unit 502 used for acquiring a pulse function represented on the basis of discrete time slices, wherein pulse parameter values within a time period from start time to end time of a time slice are the same;

a step size determination unit 503 used for determining target step sizes corresponding to the discrete time slices in the pulse function;

a pulse parameter value determination unit 504 used for obtaining pulse parameter values within time durations corresponding to the target step sizes according to the target step sizes corresponding to the time slices and the pulse function; and

a simulation unit 505 used for obtaining simulation quantum gates within the time durations corresponding to the target step sizes on the basis of obtained pulse parameter values within the time durations corresponding to the target step sizes and the hardware parameter of the quantum system, until obtaining a target simulation quantum gate within a preset pulse time duration, wherein a difference between the target simulation quantum gate within the preset pulse time duration and the target quantum gate meets a preset rule.

In a specific example of a scheme of the present disclosure, the target step sizes corresponding to respective time slices are the same or different.

In a specific example of the scheme of the present disclosure, the step size determination unit includes:

a first step size acquisition subunit used for acquiring a first initialization step size;

a first difference value calculation subunit used for obtaining a difference value between pulse parameter values at adjacent moments by calculating based on the first initialization step size and the pulse function; and

a first step size determination subunit used for taking the first initialization step size as the target step size, in response to determining that the difference value between the pulse parameter values at the adjacent moments is smaller than a preset pulse threshold value and a time period corresponding to the first initialization step size does not exceed the preset pulse time duration.

In a specific example of the scheme of the present disclosure, the step size determination unit includes:

a second step size acquisition subunit used for acquiring a second initialization step size;

a second difference value calculation subunit used for obtaining a difference value between pulse parameter values at adjacent moments by calculating based on the second initialization step size and the pulse function;

a step size adjusting subunit used for adjusting the second initialization step size in response to determining that the difference value between the pulse parameter values at the adjacent moments is greater than or equal to a preset pulse threshold value, until a difference value between pulse parameter values at adjusted adjacent moments is smaller than the pulse threshold value; and

a second step size determination subunit used for taking an adjusted second initialization step size with a difference value between pulse parameter values at adjacent moments smaller than the pulse threshold value as the target step size, in response to determining that a time period corresponding to the adjusted second initialization step size does not exceed the preset pulse time duration.

In a specific example of the scheme of the present disclosure, the apparatus further includes a data processing rule determination unit, wherein

the data processing rule determination unit is used for determining a total Hamiltonian corresponding to the quantum system and obtaining a first mapping relation between a time evolution operator and the total Hamiltonian, wherein the total Hamiltonian at least includes a pulse Hamiltonian, and the pulse Hamiltonian includes the pulse function related to time information for controlling pulses; determining a data processing rule of the time evolution operator by performing a mathematical transformation on the first mapping relation based on the pulse function represented on the basis of the discrete time slices;

the simulation unit is further used for inputting the obtained pulse parameter values within the time durations corresponding to the target step sizes and the hardware parameter of the quantum system into the data processing rule, to obtain the simulation quantum gates within the time durations corresponding to the target step sizes.

As such, according to the scheme provided by the present disclosure, the time can be sliced, so that the quantum simulation can be rapidly and accurately realized, and the target simulation quantum gate obtained in the simulation process can be considered to be the target quantum gate planned to be realized, thereby laying a foundation for more efficient realization of the quantum gate.

According to an embodiment of the present disclosure, the present disclosure also provides a classical computer and a readable storage medium.

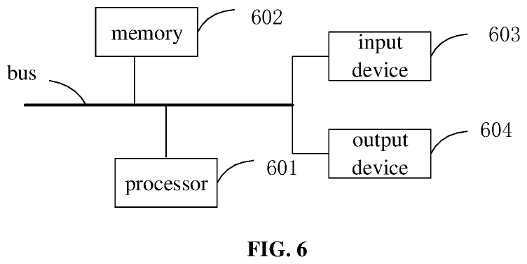

FIG. 6 is a block diagram of a classical computer for a simulation method in quantum control according to an embodiment of the present disclosure. The classical computer is intended to represent various forms of digital computers, such as laptop computers, desktop computers, workstations, personal digital assistants, servers, blade servers, mainframe computers, and other suitable computers. The components shown herein, their connections and relationships, and their functions are merely examples, and are not intended to limit the implementation of the present disclosure described and/or claimed herein.

As shown in FIG. 6, the classical computer includes: one or more processors 601, memory 602, and interfaces for connecting various components, including high-speed interface and low-speed interface. The various components are interconnected using different buses and may be installed on a common motherboard or otherwise as desired. The processor may process instructions for execution within a classical computer, including instructions stored in the memory or on the memory to display graphical information of the GUI on an external input/output device, (such as display equipment coupled to the interface). In other implementation modes, multiple processors and/or multiple buses may be used with multiple memories and multiple memories, if desired. Also, multiple classical computers may be connected, each piece of equipment providing some of the necessary operations (e.g., as an array of a server, one set of blade servers, or a multiprocessor system). An example of one processor 601 is shown in FIG. 6.

The memory 602 is a non-transitory computer-readable storage medium provided herein. Where the memory stores an instruction executable by at least one processor to cause the at least one processor to execute the simulation method in quantum control provided herein. The non-transitory computer-readable storage medium of the present disclosure stores computer instructions for causing a computer to execute the simulation method in quantum control provided herein.

The memory 602 serves as a non-transitory computer-readable storage medium and can be used for storing non-transitory software programs, non-transitory computer-executable programs and modules, and a program instruction/module corresponding to the simulation method in the quantum control in the embodiment of the present disclosure (for example, the data acquisition unit 501, the function acquisition unit 502, the step size determination unit 503, the pulse parameter value determination unit 504 and the simulation unit 505 shown in FIG. 5, and a data processing rule determination unit not shown in FIG. 5). The processor 601 executes various functional present disclosures and data processing of the server, i.e., implementing the simulation method in quantum control in the above-described method embodiment, by running non-transient software programs, instructions, and modules stored in the memory 602.

The memory 602 may include a storage program area and a storage data area. The storage program area may store an operating system and an application program required for at least one function. The storage data area may store data or the like created according to the usage of the classical computer of the simulation method in quantum control. In addition, the memory 602 may include high speed random access memory, and may also include non-transitory memory, such as at least one disk storage component, flash memory component, or other non-transitory solid state storage components. In some embodiments, the memory 602 optionally includes memory remotely set relative to the processor 601. The remote memory may be connected to the classical computer of the simulation method in quantum control via a network. Instances of such networks include, but are not limited to, the Internet, intranets, local area networks, mobile communication networks, and combinations thereof.

The classical computer of the simulation method in quantum control may further include: an input device 603 and an output device 604. The processor 601, memory 602, input device 603, and output device 604 may be connected through a bus or other means, exemplified through a bus connection in FIG. 6.

The input device 603 may receive input numeric or character information and generate key signal input related to the user setting and functional control of the classical computer of the simulation method in quantum control, for example, input devices including touch screen, keypad, mouse, track pad, touch pad, indicating arm, one or more mouse buttons, trackball, joystick, etc. The output device 604 may include display equipment, an auxiliary lighting device (e.g., LED), a tactile feedback device (e.g., vibration motor), etc. The display equipment may include, but is not limited to, a liquid crystal display (LCD), a light-emitting diode (LED) display, and a plasma display. In some implementation modes, the display equipment may be a touch screen.

Various implementation modes of the system and technology described herein may be implemented in digital electronic circuit systems, integrated circuit systems, present disclosure-specific ASIC (present disclosure-specific integrated circuit), computer hardware, firmware, software, and/or combinations thereof. These various implementation modes may include: implementing in one or more computer programs, which can be executed and/or interpreted on a programmable system including at least one programmable processor. The programmable processor can be a dedicated or general-purpose programmable processor, which can receive data and instructions from, and transmit the data and instructions to, a memory system, at least one input device, and at least one output device.

These computing programs (also referred to as program, software, software present disclosure, or code) include a machine instruction of a programmable processor, and may be applied using the high-level procedure and/or object-oriented programming language, and/or assembly/machine language. As used herein, the terms “machine-readable medium” and “computer-readable medium” refer to any computer program product, equipment, and/or device (e.g., magnetic disk, optical disk, memory, programmable logic device (PLD)) for providing machine instructions and/or data to the programmable processor, including a machine-readable medium that receives a machine instruction as a machine-readable signal. The term “machine-readable signal” refers to any signal used to provide machine instructions and/or data to a programmable processor.

To provide the interaction with a user, the system and technology described herein may be applied on a computer having: a display device (e.g., a CRT (cathode ray tube) or LCD (liquid crystal display) monitor) for displaying information to the user; and a keyboard and a pointing device (e.g., a mouse or a trackball) through which the user can provide input to the computer. Other types of devices may also be used to provide the interaction with a user: for example, the feedback provided to the user may be any form of sensory feedback (e.g., visual feedback, auditory feedback, or tactile feedback); and input from the user may be received in any form (including acoustic input, voice input, or tactile input).

The system and technology described herein may be applied in a computing system that includes a background component (e.g., as a data server), or a computing system that includes a middleware component (e.g., an present disclosure server), or a computing system that includes a front-end component (e.g., a user computer having a graphical user interface or a web browser, wherein a user may interact with implementation modes of the system and technology described herein through the graphical user interface or the web browser), or a computing system that includes any combination of such background component, middleware component, or front-end component. The components of the system may be interconnected by any form or medium of the digital data communication (e.g., a communication network). Examples of the communication network include: Local Area Networks (LAN), Wide Area Network (WAN), and the Internet.

A computer system may include a client and a server. The client and server are typically remote from each other and typically interact through a communication network. The relationship of the client and the server is generated by computer programs running on the respective computer and having a client-server relationship with each other. The server can be a cloud server, also called a cloud computing server or a cloud host, being a host product in a cloud computing service system, for solving the defects of high management difficulty and weak business extension in the conventional physical host and virtual private server (VPS) service. The server may also be a server of a distributed system, or a server incorporating a blockchain.

As such, according to the technical scheme provided by an embodiment of the present disclosure, the time can be sliced, so that the quantum simulation can be rapidly and accurately realized, and the target simulation quantum gate obtained in the simulation process can be considered to be the target quantum gate planned to be realized, thereby laying a foundation for more efficient realization of the quantum gate.

It should be understood that the various forms of flow, reordering, adding or deleting steps shown above may be used. For example, the steps recorded in the present disclosure may be executed in parallel or sequentially or may be executed in a different order, so long as the desired result of the technical scheme disclosed in the present disclosure can be achieved, and no limitation is made herein.

The above-mentioned implementation modes are not to be construed as limiting the scope of the present disclosure. It will be apparent to those skilled in the art that various modifications, combinations, sub-combinations, and substitutions can be performed according to design requirements and other factors. Any modifications, equivalents, and improvements, and the like made within the spirit and principle of the present disclosure are intended to be included within the scope of the present disclosure.

What is claimed is:

1. A simulation method in quantum control, comprising:
acquiring a hardware parameter corresponding to a quantum system and a target quantum gate required to be realized by the quantum system;
acquiring a pulse function represented on the basis of discrete time slices, wherein pulse parameter values within a time period from start time to end time of a time slice are the same;
determining target step sizes corresponding to the discrete time slices in the pulse function, to obtain pulse parameter values within time durations corresponding to the target step sizes according to the target step sizes corresponding to the time slices and the pulse function; and
obtaining simulation quantum gates within the time durations corresponding to the target step sizes on the basis of obtained pulse parameter values within the time durations corresponding to the target step sizes and the hardware parameter of the quantum system, until obtaining a target simulation quantum gate within a preset pulse time duration, wherein a difference between the target simulation quantum gate within the preset pulse time duration and the target quantum gate meets a preset rule.

2. The simulation method of claim 1, wherein the target step sizes corresponding to respective time slices are the same or different.

3. The simulation method of claim 1, wherein determining the target step sizes corresponding to the discrete time slices in the pulse function comprises:
acquiring a first initialization step size;
obtaining a difference value between pulse parameter values at adjacent moments by calculating based on the first initialization step size and the pulse function; and
taking the first initialization step size as the target step size, in response to determining that the difference value between the pulse parameter values at the adjacent moments is smaller than a preset pulse threshold value and a time period corresponding to the first initialization step size does not exceed the preset pulse time duration.

4. The simulation method of claim 2, wherein determining the target step sizes corresponding to the discrete time slices in the pulse function comprises:
acquiring a first initialization step size;
obtaining a difference value between pulse parameter values at adjacent moments by calculating based on the first initialization step size and the pulse function; and
taking the first initialization step size as the target step size, in response to determining that the difference value between the pulse parameter values at the adjacent moments is smaller than a preset pulse threshold value and a time period corresponding to the first initialization step size does not exceed the preset pulse time duration.

5. The simulation method of claim 1, wherein determining the target step sizes corresponding to the discrete time slices in the pulse function comprises:
acquiring a second initialization step size;
obtaining a difference value between pulse parameter values at adjacent moments by calculating based on the second initialization step size and the pulse function;
adjusting the second initialization step size in response to determining that the difference value between the pulse parameter values at the adjacent moments is greater than or equal to a preset pulse threshold value, until a difference value between pulse parameter values at adjusted adjacent moments is smaller than the pulse threshold value; and
taking an adjusted second initialization step size with a difference value between pulse parameter values at adjacent moments smaller than the pulse threshold value as the target step size, in response to determining that a time period corresponding to the adjusted second initialization step size does not exceed the preset pulse time duration.

6. The simulation method of claim 2, wherein determining the target step sizes corresponding to the discrete time slices in the pulse function comprises:
acquiring a second initialization step size;
obtaining a difference value between pulse parameter values at adjacent moments by calculating based on the second initialization step size and the pulse function;
adjusting the second initialization step size in response to determining that the difference value between the pulse parameter values at the adjacent moments is greater than or equal to a preset pulse threshold value, until a difference value between pulse parameter values at adjusted adjacent moments is smaller than the pulse threshold value; and
taking an adjusted second initialization step size with a difference value between pulse parameter values at adjacent moments smaller than the pulse threshold value as the target step size, in response to determining that a time period corresponding to the adjusted second initialization step size does not exceed the preset pulse time duration.

7. The simulation method of claim 1, further comprising:
determining a total Hamiltonian corresponding to the quantum system and obtaining a first mapping relation between a time evolution operator and the total Hamiltonian, wherein the total Hamiltonian at least comprises a pulse Hamiltonian, and the pulse Hamiltonian comprises the pulse function related to time information for controlling pulses; and
determining a data processing rule of the time evolution operator by performing a mathematical transformation on the first mapping relation based on the pulse function represented on the basis of the discrete time slices;
wherein obtaining the simulation quantum gates within the time durations corresponding to the target step sizes on the basis of the obtained pulse parameter values within the time durations corresponding to the target step sizes and the hardware parameter of the quantum system further comprises:
inputting the obtained pulse parameter values within the time durations corresponding to the target step sizes and the hardware parameter of the quantum system into the data processing rule, to obtain the simulation quantum gates within the time durations corresponding to the target step sizes.

8. A classic computer, comprising:
at least one processor; and
a memory communicatively connected to the at least one processor, wherein
the memory stores instructions executable by the at least one processor, and the instructions are executed by the at least one processor to enable the at least one processor to:
acquire a hardware parameter corresponding to a quantum system and a target quantum gate required to be realized by the quantum system;
acquire a pulse function represented on the basis of discrete time slices, wherein pulse parameter values within a time period from start time to end time of a time slice are the same;
determine target step sizes corresponding to the discrete time slices in the pulse function, to obtain pulse parameter values within time durations corresponding to the target step sizes according to the target step sizes corresponding to the time slices and the pulse function; and
obtain simulation quantum gates within the time durations corresponding to the target step sizes on the basis of obtained pulse parameter values within the time durations corresponding to the target step sizes and the hardware parameter of the quantum system, until obtaining a target simulation quantum gate within a preset pulse time duration, wherein a difference between the target simulation quantum gate within the preset pulse time duration and the target quantum gate meets a preset rule.

9. The classic computer according to claim 8, wherein the target step sizes corresponding to respective time slices are the same or different.

10. The classic computer according to claim 8, wherein the instructions are executed by the at least one processor to further enable the at least one processor to:
acquire a first initialization step size;
obtain a difference value between pulse parameter values at adjacent moments by calculating based on the first initialization step size and the pulse function; and
take the first initialization step size as the target step size, in response to determining that the difference value between the pulse parameter values at the adjacent moments is smaller than a preset pulse threshold value and a time period corresponding to the first initialization step size does not exceed the preset pulse time duration.

11. The classic computer according to claim 9, wherein the instructions are executed by the at least one processor to further enable the at least one processor to:
acquire a first initialization step size;
obtain a difference value between pulse parameter values at adjacent moments by calculating based on the first initialization step size and the pulse function; and
take the first initialization step size as the target step size, in response to determining that the difference value between the pulse parameter values at the adjacent moments is smaller than a preset pulse threshold value and a time period corresponding to the first initialization step size does not exceed the preset pulse time duration.

12. The classic computer according to claim 8, wherein the instructions are executed by the at least one processor to further enable the at least one processor to:
acquire a second initialization step size;
obtain a difference value between pulse parameter values at adjacent moments by calculating based on the second initialization step size and the pulse function;
adjust the second initialization step size in response to determining that the difference value between the pulse parameter values at the adjacent moments is greater than or equal to a preset pulse threshold value, until a difference value between pulse parameter values at adjusted adjacent moments is smaller than the pulse threshold value; and
take an adjusted second initialization step size with a difference value between pulse parameter values at adjacent moments smaller than the pulse threshold value as the target step size, in response to determining that a time period corresponding to the adjusted second initialization step size does not exceed the preset pulse time duration.

13. The classic computer according to claim 9, wherein the instructions are executed by the at least one processor to further enable the at least one processor to:
acquire a second initialization step size;
obtain a difference value between pulse parameter values at adjacent moments by calculating based on the second initialization step size and the pulse function;
adjust the second initialization step size in response to determining that the difference value between the pulse parameter values at the adjacent moments is greater than or equal to a preset pulse threshold value, until a difference value between pulse parameter values at adjusted adjacent moments is smaller than the pulse threshold value; and
take an adjusted second initialization step size with a difference value between pulse parameter values at adjacent moments smaller than the pulse threshold value as the target step size, in response to determining that a time period corresponding to the adjusted second initialization step size does not exceed the preset pulse time duration.

14. The classic computer according to claim 8, wherein the instructions are executed by the at least one processor to further enable the at least one processor to:
determine a total Hamiltonian corresponding to the quantum system and obtaining a first mapping relation between a time evolution operator and the total Hamiltonian, wherein the total Hamiltonian at least comprises a pulse Hamiltonian, and the pulse Hamiltonian comprises the pulse function related to time information for controlling pulses; and
determine a data processing rule of the time evolution operator by performing a mathematical transformation on the first mapping relation based on the pulse function represented on the basis of the discrete time slices;
wherein obtaining the simulation quantum gates within the time durations corresponding to the target step sizes on the basis of the obtained pulse parameter values within the time durations corresponding to the target step sizes and the hardware parameter of the quantum system further comprises:
inputting the obtained pulse parameter values within the time durations corresponding to the target step sizes and the hardware parameter of the quantum system into the data processing rule, to obtain the simulation quantum gates within the time durations corresponding to the target step sizes.

15. A non-transitory computer-readable storage medium storing computer instructions, wherein the computer instructions, when executed by a computer, cause the computer to:
acquire a hardware parameter corresponding to a quantum system and a target quantum gate required to be realized by the quantum system;
acquire a pulse function represented on the basis of discrete time slices, wherein pulse parameter values within a time period from start time to end time of a time slice are the same;
determine target step sizes corresponding to the discrete time slices in the pulse function, to obtain pulse parameter values within time durations corresponding to the target step sizes according to the target step sizes corresponding to the time slices and the pulse function; and
obtain simulation quantum gates within the time durations corresponding to the target step sizes on the basis of obtained pulse parameter values within the time durations corresponding to the target step sizes and the hardware parameter of the quantum system, until obtaining a target simulation quantum gate within a preset pulse time duration, wherein a difference between the target simulation quantum gate within the preset pulse time duration and the target quantum gate meets a preset rule.

16. The non-transitory computer-readable storage medium according to claim 15, wherein the target step sizes corresponding to respective time slices are the same or different.

17. The non-transitory computer-readable storage medium according to claim 15, wherein the computer instructions, when executed by a computer, further cause the computer to:
acquire a first initialization step size;
obtain a difference value between pulse parameter values at adjacent moments by calculating based on the first initialization step size and the pulse function; and
take the first initialization step size as the target step size, in response to determining that the difference value between the pulse parameter values at the adjacent moments is smaller than a preset pulse threshold value and a time period corresponding to the first initialization step size does not exceed the preset pulse time duration.

18. The non-transitory computer-readable storage medium according to claim 16, wherein the computer instructions, when executed by a computer, further cause the computer to:
acquire a first initialization step size;
obtain a difference value between pulse parameter values at adjacent moments by calculating based on the first initialization step size and the pulse function; and
take the first initialization step size as the target step size, in response to determining that the difference value between the pulse parameter values at the adjacent moments is smaller than a preset pulse threshold value and a time period corresponding to the first initialization step size does not exceed the preset pulse time duration.

19. The non-transitory computer-readable storage medium according to claim 15, wherein the computer instructions, when executed by a computer, further cause the computer to:
acquire a second initialization step size;
obtain a difference value between pulse parameter values at adjacent moments by calculating based on the second initialization step size and the pulse function;
adjust the second initialization step size in response to determining that the difference value between the pulse parameter values at the adjacent moments is greater than or equal to a preset pulse threshold value, until a difference value between pulse parameter values at adjusted adjacent moments is smaller than the pulse threshold value; and
take an adjusted second initialization step size with a difference value between pulse parameter values at adjacent moments smaller than the pulse threshold value as the target step size, in response to determining that a time period corresponding to the adjusted second initialization step size does not exceed the preset pulse time duration.

20. The non-transitory computer-readable storage medium according to claim 15, wherein the computer instructions, when executed by a computer, further cause the computer to:
determine a total Hamiltonian corresponding to the quantum system and obtaining a first mapping relation between a time evolution operator and the total Hamiltonian, wherein the total Hamiltonian at least comprises a pulse Hamiltonian, and the pulse Hamiltonian comprises the pulse function related to time information for controlling pulses; and
determine a data processing rule of the time evolution operator by performing a mathematical transformation on the first mapping relation based on the pulse function represented on the basis of the discrete time slices;
wherein obtaining the simulation quantum gates within the time durations corresponding to the target step sizes on the basis of the obtained pulse parameter values within the time durations corresponding to the target step sizes and the hardware parameter of the quantum system further comprises:
inputting the obtained pulse parameter values within the time durations corresponding to the target step sizes and the hardware parameter of the quantum system into the data processing rule, to obtain the simulation quantum gates within the time durations corresponding to the target step sizes.
